(19) United States
(12) Patent Application Publication
(10) Pub. No.: US 2018/0374720 A1
(43) Pub. Date: Dec. 27, 2018

(54) GAS EXHAUST PLATE AND PLASMA PROCESSING APPARATUS

(71) Applicant: Tokyo Electron Limited, Tokyo (JP)

(72) Inventors: Shinji Himori, Kurokawa-gun (JP); Jun Abe, Kurokawa-gun (JP)

(21) Appl. No.: 16/010,658

(22) Filed: Jun. 18, 2018

(30) Foreign Application Priority Data
Jun. 23, 2017 (JP) 2017-123656

(51) Int. Cl. H01L 21/67; H01J 37/32

(52) U.S. Cl. CPC H01L 21/67017; H01J 2237/0262; H01J 37/32834; H01J 37/32633

(57) ABSTRACT

A gas exhaust plate capable of improving a confinement effect of plasma while achieving sufficient conductance is provided. The gas exhaust plate is provided between a sidewall of a processing vessel of a plasma processing apparatus and a mounting table provided within the processing vessel, and is configured to separate a processing space in which a processing is performed by a plasmarized gas from a gas exhaust space which is adjacent to the processing space and through which a gas generated by the processing is exhausted. The gas exhaust plate includes a porous metal sheet.

### CROSS-REFERENCE TO RELATED APPLICATION

This application claims the benefit of Japanese Patent Application No. 2017-123656 filed on Jun. 23, 2017, the entire disclosures of which are incorporated herein by reference.

### TECHNICAL FIELD

The embodiments described herein pertain generally to a gas exhaust plate and a plasma processing apparatus.

### BACKGROUND

Conventionally, there is known a plasma processing apparatus configured to perform a processing on a substrate by generating plasma within a hermetically sealable processing vessel. As such a plasma processing apparatus, there is known a configuration in which a gas exhaust plate is provided to separate a processing space in which the processing is performed by a plasmarized gas and a gas exhaust space which is adjacent to the processing space and through which a gas generated by the processing is exhausted.

A configuration in which a mesh member, or a metal plate member provided with a multiple number of openings such as through holes or slits may be used as the gas exhaust plate is known (for example, Patent Documents 1 to 3), for example. Such a gas exhaust plate is required to improve an effect of confining the plasma into the processing space while achieving sufficient conductance into the gas exhaust space from the processing space.

As a way to improve the confinement effect of the plasma by using the gas exhaust plate, there may be employed a method of, for example, setting a size of the individual openings to be small to block charged particles such as ions and electrons from being passed therethrough, thus suppressing the charged particles from being introduced into the gas exhaust space.
Patent Document 1: Japanese Patent Laid-open Publication No. 2001-179078
Patent Document 2: Japanese Patent Laid-open Publication No. 2011-040461
Patent Document 3: Japanese Patent Laid-open Publication No. H10-321605

If the size of the openings is reduced, however, the conductance may be deteriorated, resulting in a failure to acquire a sufficient gas flow rate from the processing space into the gas exhaust space. Meanwhile, if the conductance is achieved by increasing a total number of the openings by way of, for example, increasing a size of the gas exhaust plate, a footprint and a manufacturing cost of the apparatus may be increased due to the increase of the size of the processing vessel.

As stated above, in the conventional gas exhaust plate, the confinement effect of the plasma and the size of the openings is in a trade-off relationship. Thus, it has been difficult to improve the plasma confinement effect while achieving the conductance at the same time.

### SUMMARY

In view of the foregoing, exemplary embodiments provide a gas exhaust plate capable of improving a confinement effect of plasma while achieving sufficient conductance.

In an exemplary embodiment, there is provided a gas exhaust plate which is provided within a processing vessel configured to process a substrate by generating plasma therein and which is configured to separate an inside of the processing vessel into a processing space in which the substrate is processed and a gas exhaust space through which a gas is exhausted from the inside of the processing vessel. The gas exhaust plate includes a porous metal sheet.

According to the gas exhaust plate as described above, it is possible to improve a confinement effect of plasma while achieving sufficient conductance.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a schematic diagram illustrating a plasma processing apparatus according to an exemplary embodiment;

FIG. 2A and FIG. 2B are diagrams illustrating an example of a baffle plate according to the exemplary embodiment;

FIG. 3A and FIG. 3B are diagrams illustrating another example of the baffle plate according to the exemplary embodiment;

FIG. 4 is a diagram for describing an effect of a porous metal sheet;

FIG. 5 is a diagram for describing a conventional bulk metal plate;

FIG. 6 is a schematic diagram illustrating an apparatus for evaluating conductance and blocking characteristic of electrons;

FIG. 7A and FIG. 7B are plan views illustrating an example of an aperture including the porous metal sheet according to an experimental example;

FIG. 8 is a plan view illustrating an aperture according to a comparative example;

FIG. 9A and FIG. 9B are diagrams showing a result of investigating a blocking effect against electrons in each of the cases of using the aperture according to the experimental example and the aperture according to the comparative example;

FIG. 10 is a plan view illustrating an example of an aperture according to an experimental example;

FIG. 11 is a plan view illustrating an aperture according to a comparative example; and

FIG. 12 is a diagram showing a result of investigating the conductance in each of the cases of using the aperture according to the experimental example and the aperture according to the comparative example.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described with reference to the accompanying drawings. In the specification and the various drawings, substantially same parts will be assigned same reference numerals, and redundant description thereof will be omitted.

A gas exhaust plate according to an exemplary embodiment is a baffle plate which is provided between a sidewall of a processing vessel of a plasma processing apparatus and a mounting table provided within the processing vessel, and which is configured to separate a processing space from a gas exhaust space. The processing space is a region in which a processing is performed by a plasmarized gas. The gas exhaust space is a region which is adjacent to the processing space and through which a gas generated by the processing is exhausted. Here, the baffle plate includes a porous metal sheet. Accordingly, it is possible to improve an effect of confining the plasma (confinement effect of the plasma) while achieving conductance.

(Plasma Processing Apparatus)

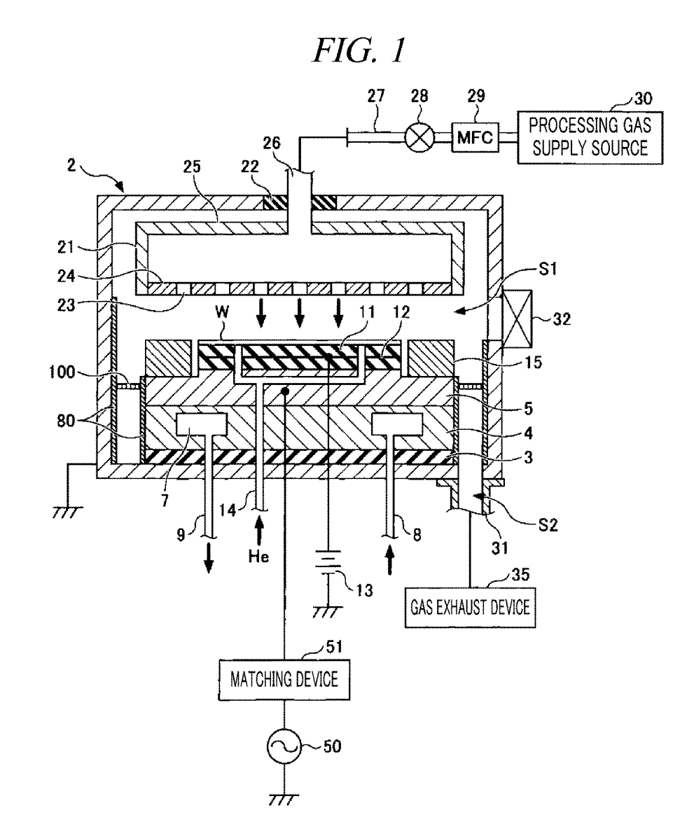

First, an example of a plasma processing apparatus to which the baffle plate according to the present exemplary embodiment is applied will be explained. FIG. 1 is a schematic diagram illustrating the plasma processing apparatus according to the exemplary embodiment.

As depicted in FIG. 1, the plasma processing apparatus according to the exemplary embodiment is equipped with a substantially cylindrical processing vessel 2 having a surface made of, by way of example, anodically oxidized aluminum. The processing vessel 2 is grounded.

A substantially circular column-shaped susceptor supporting table 4 is provided on a bottom portion of the processing vessel 2 with an insulating plate 3 such as ceramic therebetween. A susceptor 5 configured as a mounting table serving as a lower electrode is provided on the susceptor supporting table 4.

A coolant path 7 is provided within the susceptor supporting table 4. A coolant is introduced from a coolant inlet line 8 into the coolant path 7 to be circulated therein and is exhausted through a coolant outlet line 9. Accordingly, a cold heat is transferred through the susceptor 5 to a substrate W placed on the susceptor 5, so that the substrate W is controlled to have a required temperature.

An upper central portion of the susceptor 5 is formed to have a circular plate shape protruding higher than a peripheral portion thereof. A circular electrostatic chuck 11 having the substantially same diameter as the substrate W such as a semiconductor wafer is provided on the upper central portion of the susceptor 5. The electrostatic chuck 11 has an electrode 12 embedded in an insulating member. The electrode 12 is connected with a DC power supply 13. The substrate W is attracted to and held by the electrostatic chuck 11 with a Coulomb force generated by a DC voltage applied from the DC power supply 13.

The insulating plate 3, the susceptor supporting table 4, the susceptor 5 and the electrostatic chuck 11 is provided with a gas passage 14 through which a heat transfer medium (for example, a He gas) is supplied to a rear surface of the substrate W. The cold heat of the susceptor 5 is transferred to the substrate W through the heat transfer medium, so that the substrate W is maintained at the preset temperature.

An annular focus ring 15 is disposed at an upper peripheral portion of the susceptor 5 to surround the substrate W placed on the electrostatic chuck 11. The focus ring 15 is made of a conductive material such as, but not limited to, silicon and configured to improve etching uniformity.

An upper electrode 21 is disposed above the susceptor 5, facing the susceptor 5. The upper electrode 21 is supported at an upper portion of the processing vessel 2 with an insulating member 22 therebetween. The upper electrode 21 includes an electrode plate 24; and an electrode supporting member 25 made of a conductive material and configured to support the electrode plate 24. The electrode plate 24 is made of a semiconductor or a conductor such as, but not limited to Si or SiC, and is provided with a multiple number of discharge holes 23. The electrode plate 24 serves as a facing surface to the susceptor 5.

A gas inlet port 26 is provided at the center of the electrode supporting member 25 of the upper electrode 21, and the gas inlet port 26 is connected with a gas supply line 27. The gas supply line 27 is connected to a processing gas supply source 30 via an opening/closing valve 28 and a mass flow controller 29. The processing gas supply source 30 is configured to supply an etching gas for a plasma etching processing.

A gas exhaust line 31 is connected to the bottom portion of the processing vessel 2, and the gas exhaust line 31 is connected to a gas exhaust device 35. The gas exhaust device 35 is equipped with a vacuum pump such as a turbo molecular pump and configured to evacuate the inside of the processing vessel 2 to create a preset decompressed atmosphere therein. Further, a gate valve 32 is provided at the sidewall of the processing vessel 2. With the gate valve 32 open, the substrate W can be carried into the processing vessel 2.

A high frequency power supply 50 is connected to the susceptor 5 serving as the lower electrode, and a matching device 51 is provided between the high frequency power supply 50 and the lower electrode. By applying a high frequency power to the lower electrode from the high frequency power supply 50, plasma can be generated within the processing vessel 2.

Further, a deposition shield 80 is provided along an inner wall of the processing vessel 2 in a detachable manner to suppress an etching byproduct (deposit) from adhering to the processing vessel 2. Further, the deposition shield 80 is also provided on outer side surfaces of the susceptor supporting table 4 and the susceptor 5.

An annular baffle plate 100 is provided between the sidewall of the processing vessel 2 and the susceptor 5, that is, between the deposition shield 80 at the side of the processing vessel 2 and the deposition shield 80 at the side of the susceptor 5. Each of the deposition shield 80 and the baffle plate 100 may be implemented by an aluminum member coated with ceramic such as alumina or yttria (Y₂O₃).

The baffle plate 100 is configured to enable a uniform gas exhaust from an annular region around the susceptor 5, and partitions the inside of the processing vessel 2 into a processing space S1 for accommodating and processing the substrate W therein and a gas exhaust space S2 for performing a gas exhaust under the processing space S1. Accordingly, introduction of the plasma into the gas exhaust space S2 under the baffle plate 100 can be suppressed. The baffle plate 100 is an example of the gas exhaust plate.

The baffle plate 100 is required to improve the confinement effect of the plasma into the processing space while acquiring sufficient conductance into the gas exhaust space from the processing space. A conventional baffle plate is implemented by a mesh member or a metal plate member provided with a multiple number of openings such as through holes or slits. Thus, to improve the confinement effect of the plasma, a size of the individual openings needs to be set to be small to block a passage of charged particles such as ions and electrons, thus suppressing the charged particles from being introduced into the gas exhaust space. Further, there may also be employed a method of increasing a thickness of the baffle plate.

If the size of the openings is reduced, however, the conductance may be deteriorated, resulting in a failure to acquire a sufficient gas flow rate from the processing space into the gas exhaust space. Meanwhile, if the conductance is achieved by, for example, increasing the total number of the openings by way of increasing the size of the baffle plate, a problem such as an increase of the footprint may be caused due to the increase of the size of the processing vessel.

As stated above, in the conventional baffle plate, since the confinement effect of the plasma and the size of the openings is in a trade-off relationship, it has been difficult to improve the plasma confinement effect while acquiring the conductance as well.

In this regard, the present inventors have conducted investigation over the problem of the prior art and found out that, by using the baffle plate including the porous metal sheet, the confinement effect of the plasma can be bettered while the conductance is also achieved. In the following description, the baffle plate capable of improving the confinement effect of the plasma while achieving the conductance will be described in detail.

(Baffle Plate)

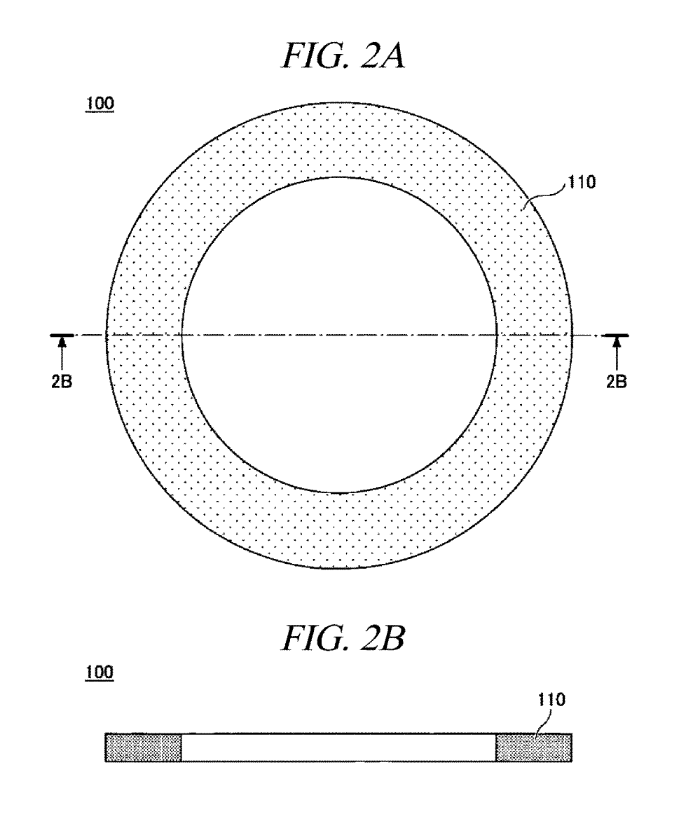

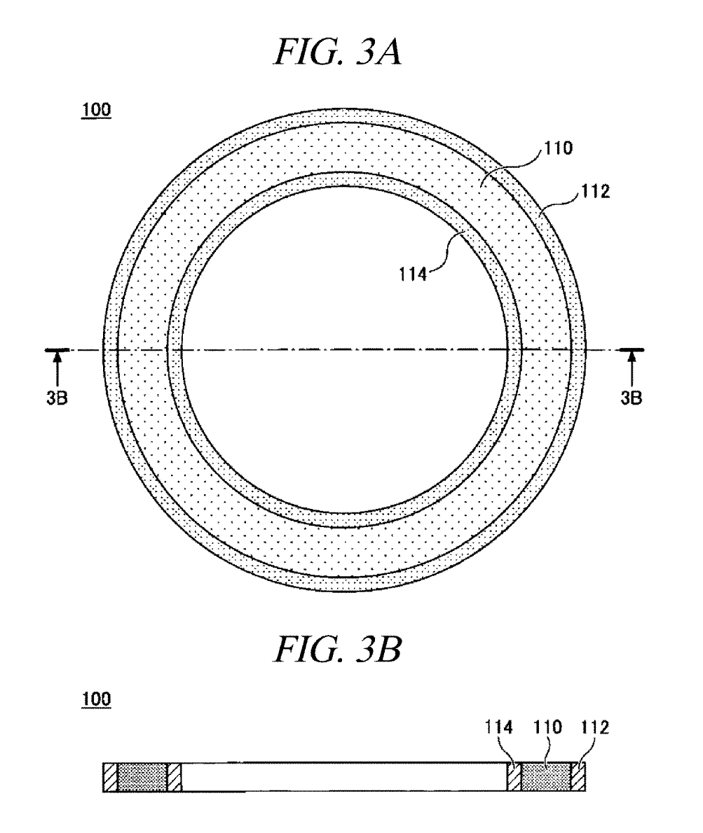

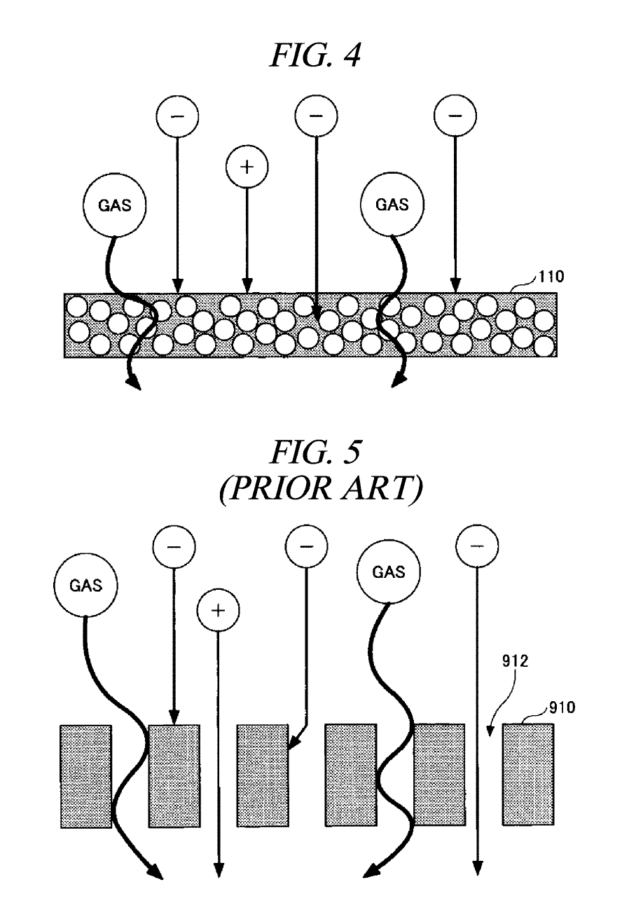

The baffle plate 100 according to the present exemplary embodiment will be explained. FIG. 2A and FIG. 2B are diagrams illustrating an example of the baffle plate according to the exemplary embodiment. FIG. 2A is a plan view of the baffle plate, and FIG. 2B is a cross sectional view taken along a dashed dotted line 2B-2B of FIG. 2A. FIG. 3A and FIG. 3B are diagrams illustrating another example of the baffle plate according to the exemplary embodiment. FIG. 3A is a plan view of the baffle plate, and FIG. 3B is a cross sectional view taken along a dashed dotted line 3B-3B of FIG. 3A. FIG. 4 is a diagram for describing an effect of the porous metal sheet. FIG. 5 is a diagram for describing a conventional bulk metal plate.

The baffle plate 100 according to the present exemplary embodiment includes a porous metal sheet at least at a part thereof. As shown in FIG. 2A and FIG. 2B, the baffle plate 100 may be, for example, a porous metal sheet 110 having an annular shape. Further, as shown in FIG. 3A and FIG. 3B, the baffle plate 100 may be composed of, for example, the porous metal sheet 110 having an annular shape, a first metal member 112 and a second metal member 114. The first metal member 112 is connected to an outer circumferential portion of the porous metal sheet 110 and is made of a bulk metal material having an annular plate shape. The second metal member 114 is connected to an inner circumferential portion of the porous metal sheet 110 and is made of a bulk metal material having an annular plate shape. If the baffle plate 100 is composed of the porous metal sheet 110, the first metal member 112 and the second metal member 114, strength of the baffle plate 100 can be enhanced.

According to the present exemplary embodiment, the porous metal sheet 110 is made of metal fibers. In this case, the metal fibers are overlapped, and spaces between the metal fibers form a curved path or a random path. Thus, since there hardly exists a straight path passing through the porous metal sheet 110, charged particles such as electrons or ions having high straightness may not pass through the porous metal sheet 110, as shown in FIG. 4. Meanwhile, a gas having low straightness can pass through the spaces between the metal fibers within the porous metal sheet 110. Therefore, though positive ions and electrons generated by ionization and dissociation of gas molecules constituting the plasma are blocked by the porous metal sheet 110, the gas which is not plasmarized may not be blocked by the porous metal sheet 110 but be discharged into the gas exhaust space S2. As a result, the confinement effect of the plasma can be improved while the conductance is still achieved. Furthermore, regarding the porous metal sheet 110, since the charged particles are moved in surfaces of the individual metal fibers, an area in which the charged particles are flown is larger, as compared to the bulk metal material. Therefore, the charged particles tend to be easily flown toward a ground line of the processing vessel 2. That is, a RF return effect is high. For the reason, the baffle plate 100 can be thinned, so that the conductance can be improved.

Meanwhile, as shown in FIG. 5, if the baffle plate is implemented by a metal plate 910 provided with openings 912 such as through holes or slits, a part of charged particles such as electrons or ions having high straightness may pass through the openings 912 which form a straight path. In view of this, it may be considered to reduce an opening diameter of the openings 912. If, however, the opening diameter of the openings 912 is reduced, the conductance is also reduced, which is regarded undesirable. Further, it may also be considered to acquire the conductance by increasing a total number of the openings 912 by way of increasing the size of the baffle plate 100. In such a case, however, the increase of the size of the processing vessel 2 may result in the increase of the footprint and the manufacturing cost of the apparatus. Therefore, this option is not desirable.

A material of the metal fibers may be, by way of example, but not limitation, stainless steel (SUS), copper (Cu), aluminum (Al), silver (Ag), or the like. From the point of view of improving the confinement effect of the plasma particularly, it is desirable that a fiber diameter of the metal fiber is set to be larger than a skin depth which is determined based on a frequency of the high frequency power applied to the lower electrode from the high frequency power supply 50 in order to reduce an AC resistance value. By way of example, when using Cu, the skin depth may be about 100 μm, about 40 μm, about 20 μm, about 10 μm, and about 6.5 μm when the frequency of the high frequency power is 400 kHz, 3 MHz, 13 MHz, 40 MHz and 100 MHz, respectively. For this reason, it is desirable that the fiber diameter of the metal fiber when using the Cu as the material of the metal fibers is larger than about 100 μm, about 40 μm, about 20 μm, about 10 μm, and about 6.5 μm when the frequency of the high frequency power is 400 kHz, 3 MHz, 13 MHz, 40 MHz and 100 MHz, respectively.

In addition, it is desirable that the porous metal sheet 110 is made of a sheet in which the metal fibers are distributed without being oriented (randomly). In case that the metal fibers are not oriented, an influence of a proximity effect due to an eddy current generated at adjacent metal fibers can be small, as compared to a case where the metal fibers are regularly oriented in a lattice pattern, for example. Therefore, the AC resistance can be reduced. Desirably, a felt of the metal fibers or a sintered body of the metal fibers may be used as the sheet in which the metal fibers are distributed without being oriented.

Moreover, it is desirable that the porous metal sheet 110 is made of a metal material having a multiple number of pores, and a curved path from the processing space S1 into the gas exhaust space S2 is formed in the porous metal sheet 110. In this case, since a through hole passing through the porous metal sheet 110 in a thickness direction thereof does not exist or hardly exists, the charged particles such as the electrons or the ions having the high straightness may not pass through the porous metal sheet 110. Meanwhile, since the curved path from the processing space S1 into the gas exhaust space S2 is formed, a gas having the low straightness can pass through the porous metal sheet 110. Accordingly, the positive ions and the electrons generated by the ionization of the gas molecules constituting the plasma are blocked by the porous metal sheet 110, whereas the gas which is not plasmarized is discharged into the gas exhaust space S2 without being blocked by the porous metal sheet 110. As a result, the confinement effect of the plasma can be improved while achieving the conductance as well. By way of example, a foamed metal may be used as the metal material having the multiple number of communicating pores.

Besides, regarding an optical characteristic of the porous metal sheet 110, it is desirable that the porous metal sheet 110 has an optical characteristic in which diffused light is transmitted but parallel light is not transmitted. Accordingly, an especially high confinement effect of the plasma can be obtained while achieving the conductance as well.

Furthermore, the baffle plate 100 may be composed of a multiple number of porous metal sheets 110 stacked on top of each other.

(Effects)

The confinement effect of the plasma when using the baffle plate according to the present exemplary embodiment is investigated by evaluating the blocking characteristic of electrons as charged particles by way of the porous metal sheet. Further, the conductance of the baffle plate is investigated by evaluating the conductance of the porous metal sheet.

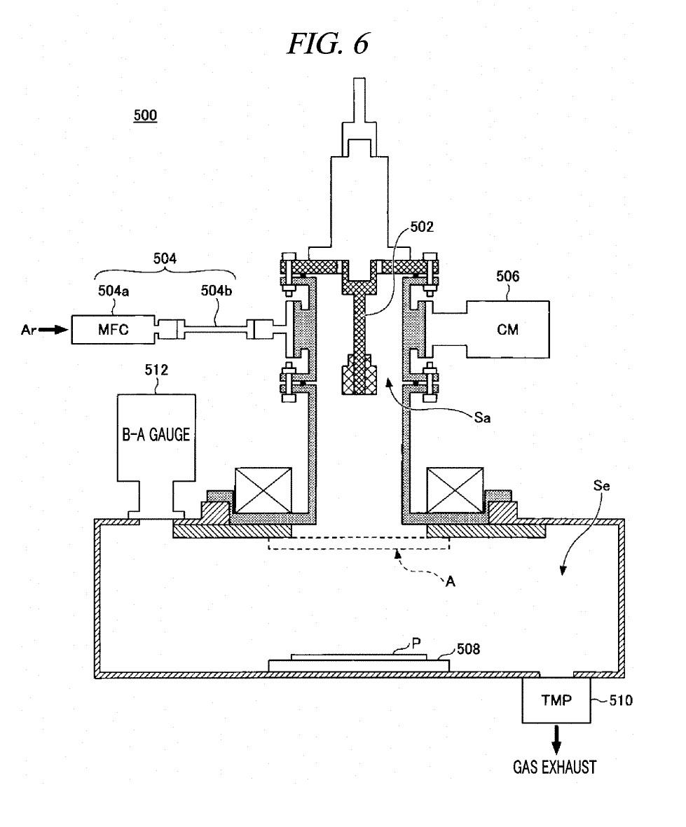

First, an evaluation apparatus used to evaluate the blocking characteristic of the electrons by the porous metal sheet and the conductance of the porous metal sheet will be explained. FIG. 6 is a schematic diagram illustrating the evaluation apparatus configured to evaluate the conductance and the blocking characteristic of the electrons.

As depicted in FIG. 6, an evaluation apparatus 500 is configured such that an aperture including the porous metal sheet is placed between an anode space Sa in which an electron gun 502 is disposed and a gas exhaust space Se communicating with the anode space Sa. In FIG. 6, a position at which the aperture is disposed is marked a region A.

The electron gun 502 is provided in the anode space Sa. The electron gun 502 is configured to irradiate an electron beam, which is generated by accelerating electrons at a preset energy (e.g., 15 keV), toward the gas exhaust space Se. Further, a gas supply unit 504 and a capacitance manometer 506 are connected to the anode space Sa. The gas supply unit 504 is configured to supply an Ar gas having a flow rate controlled by a mass flow controller 504a into the anode space Sa through a gas supply line 504b. The capacitance manometer 506 is configured to detect a pressure within the anode space Sa.

A mounting table 508 is provided in the gas exhaust space Se. The mounting table 508 is configured to mount a processing target object P thereon. Further, a turbo molecular pump 510 and a B-A gauge 512 are connected to the gas exhaust space Se. The turbo molecular pump 510 exhausts a gas within the gas exhaust space Se. The B-A gauge 512 detects a pressure within the gas exhaust space Se.

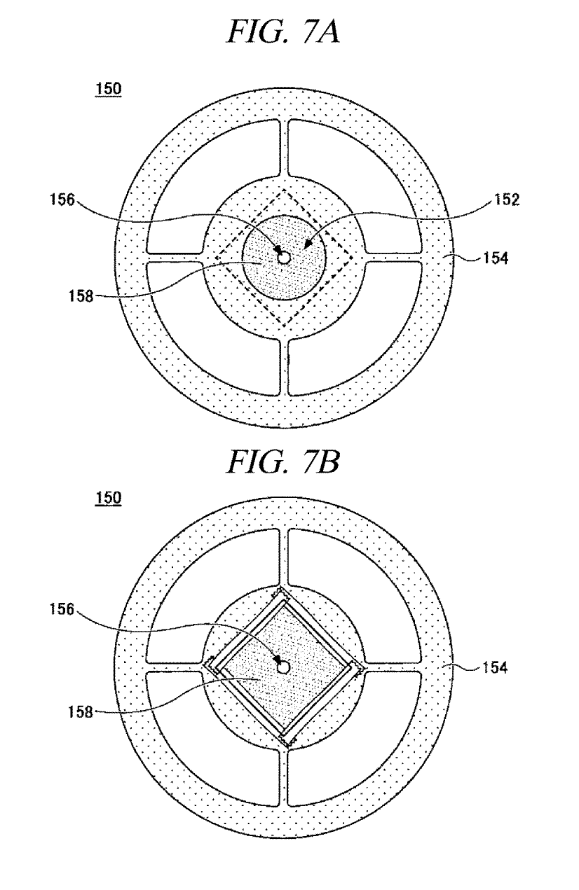

Now, the evaluation of the blocking characteristic of the electrons by the porous metal sheet, which is conducted by using the above-described evaluation apparatus 500, will be discussed. First, an aperture including a porous metal sheet used in the evaluation will be explained. FIG. 7A and FIG. 7B are plan views illustrating an example of an aperture including a porous metal sheet according to an experimental example in the present exemplary embodiment. FIG. 7A is a diagram illustrating the aperture viewed from the anode space Sa, and FIG. 7B is a diagram illustrating the aperture viewed from the gas exhaust space Se.

As depicted in FIG. 7A and FIG. 7B, an aperture 150 includes a circular plate-shaped member 154 made of a metal; and a porous metal sheet 158. The circular plate-shaped member 154 is provided with a multiple number of through holes 152 which serve as electron beam passing portions discretely distributed to allow electron beams EB to pass therethrough. The porous metal sheet 158 is attached to close a through hole 152 located at a central portion, and has an opening 156 smaller than the through hole 152 located at the central portion. The through hole 152 located at the central portion has a hole diameter of 60 mm, and the opening 156 has an opening diameter of 6 mm. A felt of metal fibers having a fiber diameter of 8 μm, a fiber length of 3 mm, a space factor of 8% and a thickness of 0.5 mm is used as the porous metal sheet 158.

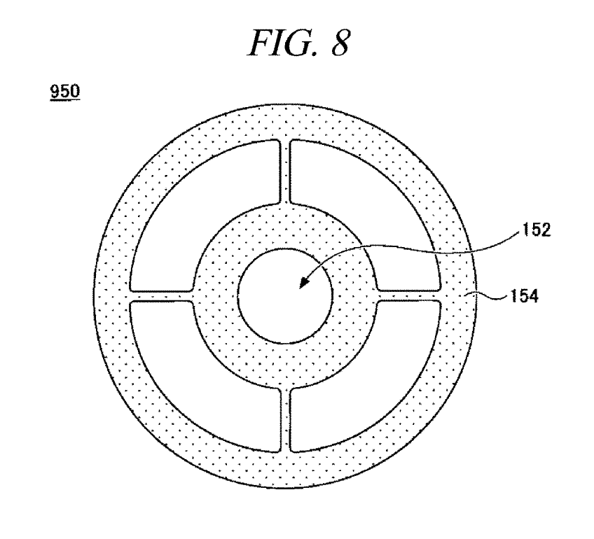

FIG. 8 is a plan view illustrating an aperture according to a comparative example. As shown in FIG. 8, an aperture 950 is prepared by removing the porous metal sheet 158 from the aperture 150 according to the experimental example. The aperture 950 is composed of the circular plate-shaped member 154 made of the same metal as that of the aperture 150 according to the experimental example.

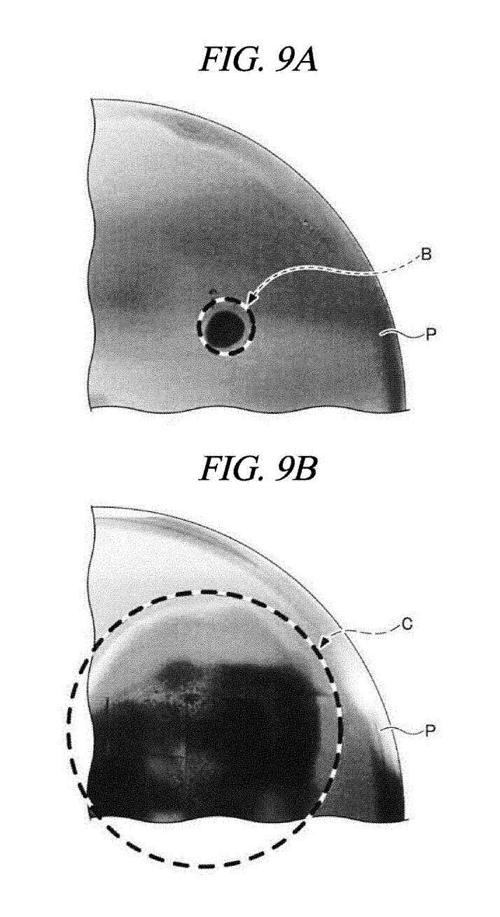

By using the above-described evaluation apparatus 500, the blocking characteristic of the electrons by the porous metal sheet 158 is investigated by irradiating the electron beams, which are generated by accelerating the electrons at 15 keV, to the processing target object P provided in the gas exhaust space Se through the apertures 150 and 950, respectively. At this time, the electron beams are irradiated through the through hole 152 located at the central portion of each of the apertures 150 and 950. FIG. 9A and FIG. 9B are diagrams showing a result of investigating the blocking characteristic of the electrons in each of cases where the aperture 150 of the experimental example and the aperture 950 of the comparative example are used. FIG. 9A shows a surface state of the processing target object P when the electron beams are irradiated to the processing target object P through the aperture 150 according to the experimental example, and FIG. 9B shows a surface state of the processing target object P when the electron beams are irradiated to the processing target object P through the aperture 950 according to the comparative example.

As depicted in FIG. 9A, in case of irradiating the electron beams to the processing target object P through the aperture 150 of the experimental example, only a position (see a region B in the figure) corresponding to the opening 156 formed at the porous metal sheet 158 is turned black, while the other positions are not. Meanwhile, as depicted in FIG. 9B, in case of irradiating the electron beams to the processing target object P through the aperture 950 of the comparative example, a position (see a region C in the figure) corresponding to the through hole 152 of the circular plate-shaped member 154 is found to be turned black. It is because the porous metal sheet 158 is not provided at the through hole 152 of the circular plate-shaped member 154. In view of this result, it is found out that the electron beams are blocked by the porous metal sheet 158 without passing through the porous metal sheet 158.

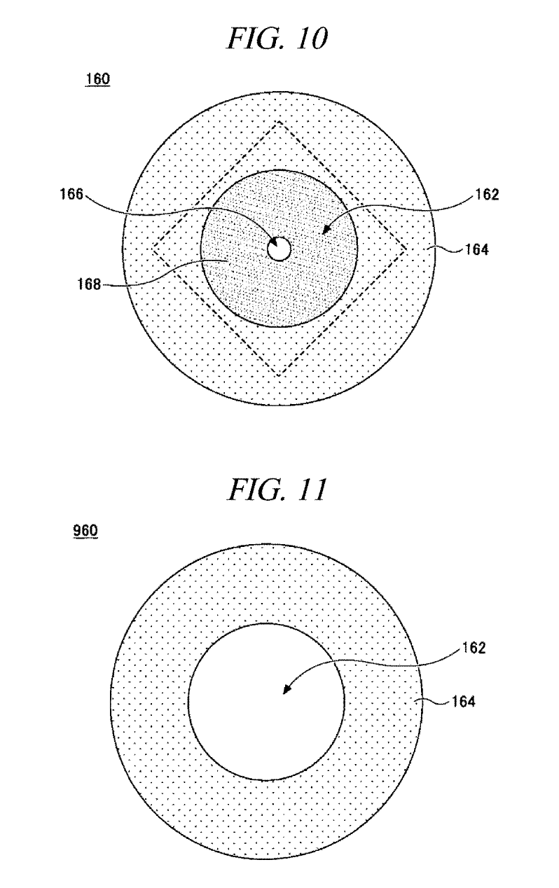

Now, the evaluation of the conductance of the aperture which is performed by using the above-described evaluation apparatus 500 will be discussed. First, an aperture used in this evaluation will be explained. FIG. 10 is a plan view illustrating an example of an aperture according to an experimental example of the present exemplary embodiment. As depicted in FIG. 10, an aperture 160 includes an annular plate-shaped member 164 which is made of a metal and which has a through hole 162 at a central portion thereof; and a porous metal sheet 168 attached to block the through hole 162 of the annular plate-shaped member 164 and having an opening 166 smaller than the through hole 162. The annular plate-shaped member 164 has an inner diameter of 60 mm and an outer diameter of 100 mm. The opening 166 has an opening diameter of 6 mm. A felt of metal fibers having a fiber diameter of 8 μm, a fiber length of 3 mm, a space factor of 8% and a thickness of 0.5 mm is used as the porous metal sheet 168.

FIG. 11 is a plan view illustrating an aperture according to a comparative example. As depicted in FIG. 11, an aperture 960 according to this comparative example is prepared by removing the porous metal sheet 168 from the aperture 160 of the experimental example. The aperture 960 is composed of the annular plate-shaped member 164 made of the same metal as that of the aperture 160 according to the experimental example.

By using the above-described evaluation apparatus 500, the aperture 160 of the experimental example and the aperture 960 of the comparative example are respectively placed between the anode space Sa and the gas exhaust space Se. Then, the Ar gas is supplied into the anode space Sa from the gas supply unit 504, and the gas exhaust space Se is evacuated by the turbo molecular pump 510. A conductance of the porous metal sheet 168 is evaluated based on a pressure within the anode space Sa detected by the capacitor manometer 506 and a pressure within the gas exhaust space Se detected by the B-A gauge.

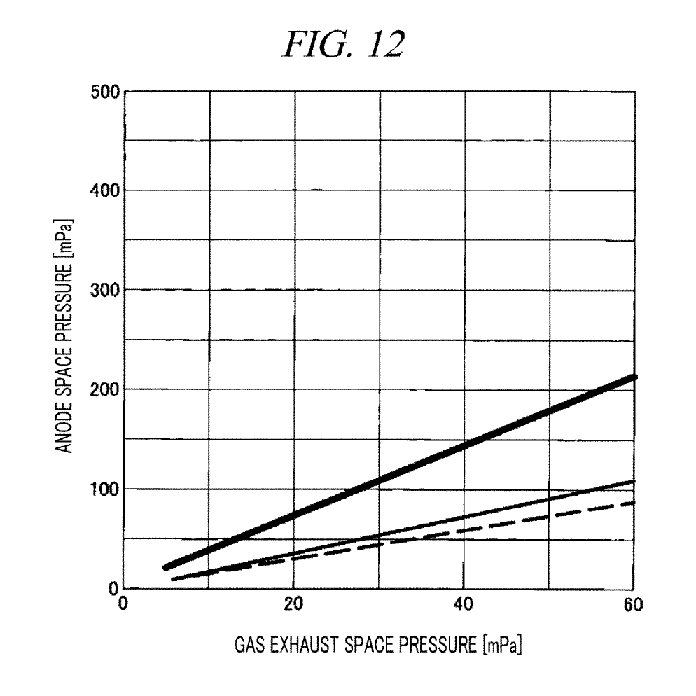

FIG. 12 is a diagram showing a result of investigating the conductance by using the aperture 160 of the experimental example and the aperture 960 of the comparative example. In FIG. 12, a horizontal axis represents a pressure mPa of the gas exhaust space Se, and a vertical axis indicates a pressure mPa of the anode space Sa. Further, in FIG. 12, a thick solid line indicates a result when the aperture 160 of the experimental example is used, a thin solid line shows a result when the aperture 960 of the comparative example is used, and a dashed line shows a result when the aperture is not provided.

As can be seen from FIG. 12, when the aperture 160 according to the experimental example of the exemplary embodiment is used, a pressure difference between the anode space Sa and the gas exhaust space Se is slightly increased as compared to the case when the aperture 960 of the comparative example is used or a case where no aperture is used. Even in case of using the aperture 160 of the experimental example, however, it is found out that a sufficient conductance is achieved as the pressure difference between the anode space Sa and the gas exhaust space Se is small. The conductance in this case is found to be 2.1 L/s·cm².

From the foregoing, it will be appreciated that the exemplary embodiment of the present disclosure has been described herein for purposes of illustration, and that various modifications may be made without departing from the scope and spirit of the present disclosure. Accordingly, the embodiment disclosed herein is not intended to be limiting. The scope of the inventive concept is defined by the following claims and their equivalents rather than by the detailed description of the exemplary embodiment. It shall be understood that all modifications and embodiments conceived from the meaning and scope of the claims and their equivalents are included in the scope of the inventive concept.

We claim:

1. A gas exhaust plate which is provided within a processing vessel configured to process a substrate by generating plasma therein and which is configured to separate an inside of the processing vessel into a processing space in which the substrate is processed and a gas exhaust space through which a gas is exhausted from the inside of the processing vessel, the gas exhaust plate comprising:
a porous metal sheet.

2. The gas exhaust plate of claim 1,
wherein the porous metal sheet is made of metal fibers.

3. The gas exhaust plate of claim 2,
wherein a material of the metal fibers includes at least one selected from a group consisting of stainless steel, copper, aluminum, and silver.

4. The gas exhaust plate of claim 1,
wherein the porous metal sheet is a sheet in which metal fibers are distributed without being oriented.

5. The gas exhaust plate of claim 1,
wherein the porous metal sheet is a felt of metal fibers or a sintered body of metal fibers.

6. The gas exhaust plate of claim 2,
wherein a fiber diameter of the metal fibers is larger than a skin depth determined based on a frequency of a high frequency power applied to the mounting table.

7. The gas exhaust plate of claim 1,
wherein the porous metal sheet is made of a metal material having multiple pores communicating with each other, and a curved path from the processing space into the gas exhaust space is formed in the porous metal sheet.

8. The gas exhaust plate of claim 7,
wherein the metal material is a foamed metal.

9. The gas exhaust plate of claim 1,
wherein diffused light is transmitted and parallel light is not transmitted in the porous metal sheet.

10. The gas exhaust plate of claim 1,
wherein the porous metal sheet includes multiple porous metal sheets, and the multiple porous metal sheets are stacked on top of each other.

11. The gas exhaust plate of claim 1, further comprising:
a first metal member connected to an outer circumferential portion of the porous metal sheet, and made of a metal material having an annular plate shape; and
a second metal member connected to an inner circumferential portion of the porous metal sheet, and made of a metal material having an annular plate shape.

12. A plasma processing apparatus comprising a processing vessel configured to process a substrate by generating plasma therein; and a gas exhaust plate which is provided within the processing vessel and which is configured to separate an inside of the processing vessel into a processing space in which the substrate is processed and a gas exhaust space through which a gas is exhausted from the inside of the processing vessel,
wherein the gas exhaust plate comprises a porous metal sheet.
